(19) United States
(12) Patent Application Publication
(10) Pub. No.: US 2023/0140222 A1
(43) Pub. Date: May 4, 2023

(54) Heated Sun Shade, Heated Solar Powered Sun Shade, and Method

(71) Applicant: Van Straten Enterprises, Inc., Chassell, MI (US)

(72) Inventor: George A. Van Straten, Chassell, MI (US)

(73) Assignee: Van Straten Enterprises, Inc., Chassell, MI (US)

(21) Appl. No.: 17/975,416

(22) Filed: Oct. 27, 2022

Related U.S. Application Data
(60) Provisional application No. 63/272,968, filed on Oct. 28, 2021.
(60) Provisional application No. 63/277,032, filed on Nov. 8, 2021.
(60) Provisional application No. 63/299,564, filed on Jan. 14, 2022.

(51) Int. Cl. B60J 1/20; H02S 40/40

(52) U.S. Cl. CPC B60J 1/2011; H02S 40/40

(57) ABSTRACT

A vehicle sun shade is provided having a sun shade, at least one solar cell, and a heat source. The sun shade has a light receiving portion configured to be carried beneath a vehicle wind shield. The at least one solar cell is provided in the light receiving portion. The heat source is provided proximate the at least one solar cell traversing the light receiving portion configured to mitigate condensate occlusion of the at least one solar cell on a vehicle wind shield. A method is also provided.

### CROSS REFERENCE TO RELATED APPLICATIONS

This patent application claims priority to and the benefit of each of U.S. Patent Application Ser. No. 63/272,968, filed 2021 Oct. 28, entitled Heated Sun Shade, Heated Solar Powered Sun Shade, and Method; U.S. Provisional Patent Application Ser. No. 63/277,032, filed 2021 Nov. 8, entitled “Heated Sun Shade, Heated Solar Powered Sun Shade, and Method”; and U.S. Provisional Patent Application Ser. No. 63/299,564, filed 2022 Jan. 14, entitled “Heated Sun Shade, Heated Solar Powered Sun Shade, and Method”; the entirety of each of which is incorporated by reference herein.

### TECHNICAL FIELD

This disclosure relates to panels and vehicle components containing solar cells and photovoltaic (PV) modules. This disclosure pertains to heated solar panels in the form of vehicle sun shades used as solar shields and to solar panels on vehicle components including vehicle glass and panels, and heated solar panels in general.

### BACKGROUND OF THE INVENTION

Techniques are known for shielding sun within a parked vehicle using folding or rolled-up sun shades. Techniques are also known for charging batteries using solar panels. Electric vehicles are also parked in sunny areas and can heat up from solar energy transferred into the vehicle. Improvements are needed to make such usage more energy efficient and to increase available real estate for providing solar panels and operating availability including when moisture or condensate occlusion can otherwise inhibit visibility and solar collection for both vehicle and mobile panel applications.

### SUMMARY OF THE INVENTION

Stowable solar panels and integrated solar panels on vehicles and portable solar panels are provided with heaters that enable a user to clear moisture or condensate occlusion, such as droplets, mist, frost, or snow, from a front surface of the solar panel and to heat vehicle windows to enable usage by a user without such occlusion. Glass integrated solar panels are provided laminated in sunroof glass and roof glass with elongate heaters. Solar panels are also provided on roof panels along with elongate heaters and in association with other vehicle components, such as tonneau covers.

According to one aspect, a vehicle sun shade is provided having a sun shade, at least one solar cell, and a heat source. The sun shade has a light receiving portion configured to be carried beneath a vehicle wind shield. The at least one solar cell is provided in the light receiving portion. The heat source is provided proximate the at least one solar cell traversing the light receiving portion configured to mitigate condensate occlusion of the at least one solar cell on a vehicle wind shield.

According to another aspect, a vehicle sun shade is provided having a sun shade and at least one solar cell. The sun shade has a light receiving portion configured to be carried beneath a vehicle wind shield. The at least one solar cell is provided in the light receiving portion.

According to yet another aspect, a method is provided for heating a vehicle sun shade. The method includes: providing a sun shade, at least one solar cell provided on the sun shade, and a heat source provided proximate the at least one solar cell; delivering power to the heat source; and generating heat from the heat source responsive to delivering power to the heat source to heat the at least one solar cell on the sun shade to mitigate any condensate or moisture occlusion of the at least one solar cell on the sun shade and/or a vehicle window in front and/or beneath the sun shade.

### BRIEF DESCRIPTION OF THE DRAWINGS

Preferred embodiments of the disclosure are described below with reference to the following accompanying drawings.

FIG. 1 is a perspective view from above of a vehicle having a stowable heated solar collector sun shade provided beneath a front windshield of the vehicle and atop a rear window sun shade.

FIG. 2 is a perspective view from above of the heated solar panel sun shade of FIG. 1.

FIG. 3 is a plan view from above of a flat, unrolled configuration of the heated solar panel sun shade of FIG. 2.

FIG. 4 is a right side view of the heated solar panel sun shade of FIG. 3.

FIG. 5 is a front edge view of the heated solar panel sun shade of FIG. 3.

FIG. 6 is a simplified front edge view of the heated solar panel sun shade of FIG. 5 being rolled up for storage.

FIG. 7 is a simplified cross-sectional view of a selected rectangular segment of the heated solar panel sun shade taken along line 7-7 of FIG. 3.

FIG. 8 is a perspective view from above of the selected segment of the heated solar panel sun shade of FIG. 7.

FIG. 9 is an exploded perspective view from above of the selected segment of the heated solar panel sun shade of FIG. 8.

FIG. 10 is a perspective view from above of a vehicle roof having a heated solar panel array integrated onto the roof.

FIG. 11 is an exploded perspective view from above of a vehicle roof having a heated solar panel array integrated into a glass roof/skylight portion of a roof.

FIG. 12 is a simplified block diagram of the heated solar panel sun shade of FIGS. 1-9 with a control and power system module used to supply and store power with the heated solar panel sun shade.

FIG. 13 is a perspective view from above and in front of an alternative vehicle roof having a heated solar panel array integrated into a laminated glass roof or sunroof of the vehicle having a polycarbonate top surface.

FIG. 14 is a perspective view from above and behind the heated solar panel array of FIG. 13.

FIG. 15 is an enlarged view of the heated solar panel array taken from encircled region 15 of FIG. 14.

FIG. 16 is an exploded perspective view of the heated solar panel array of FIGS. 13-15.

FIG. 17 is a perspective view from above and in front of a second alternative vehicle roof having a heated solar panel roof assembly, or array integrated into a laminated glass roof or sunroof of the vehicle having a polycarbonate intermediate layer.

FIG. 18 is an enlarged view of the heated solar panel taken from encircled region 18 of FIG. 17.

FIG. 19 is a perspective view from above and in front of another alternative vehicle roof having a heated solar panel array integrated into a laminated glass roof or sunroof of the vehicle having a thin film heater trace provided in a middle layer.

FIG. 20 is a perspective view from above and behind the heated solar panel array of FIG. 19.

FIG. 21 is an enlarged view of the heated solar panel taken from encircled region 21 of FIG. 20.

FIG. 22 is an exploded perspective view of the heated solar panel of FIGS. 19-21.

FIG. 23 is an enlarged view of one of the elongate heaters taken from encircled region 23 of FIG. 22.

FIG. 24 is a simplified perspective view of a laminated glass body or roof heated solar panel having a first lamination configuration relative to a pair of laminated glass panels with both a PV module and a heater array on top of a top glass panel.

FIG. 25 is a simplified perspective view of a laminated glass body or roof heated solar panel having a second lamination configuration relative to a pair of laminated glass panels with a PV module on top of a top glass panel and a heater array in a middle layer between a top glass panel and a bottom glass panel.

FIG. 26 is a simplified perspective view of a laminated glass body or roof heated solar panel having a third lamination configuration relative to a pair of laminated glass panels with a PV module on top of a top glass panel and a heater array in a bottom layer beneath a top glass panel and a bottom glass panel.

FIG. 27 is a simplified perspective view of a laminated glass body or roof heated solar panel having a fourth lamination configuration relative to a pair of laminated glass panels with a PV module in a middle layer and a heater array on top of a top glass panel.

FIG. 28 is a simplified perspective view of a laminated glass body or roof heated solar panel having a fifth lamination configuration relative to a pair of laminated glass panels with both a PV and a heater array in a middle layer between a top glass panel and a bottom glass panel.

FIG. 29 is a simplified perspective view of a laminated glass body or roof heated solar panel having a sixth lamination configuration relative to a pair of laminated glass panels with a PV module in a middle layer beneath a top glass panel and a heater array in a bottom layer beneath a top glass panel and a bottom glass panel.

FIG. 30 is a simplified perspective view of a laminated glass body or roof heated solar panel having a seventh lamination configuration relative to a pair of laminated glass panels with a PV module on a bottom layer and a heater array on top of a top glass panel.

FIG. 31 is a simplified perspective view of a laminated glass body or roof heated solar panel having an eighth lamination configuration relative to a pair of laminated glass panels with a PV module in a bottom layer beneath a bottom glass panel and a heater array in a middle layer between a top glass panel and a bottom glass panel.

FIG. 32 is a simplified perspective view of a laminated glass body or roof heated solar panel having a ninth lamination configuration relative to a pair of laminated glass panels with both a PV module and a heater array in a bottom layer beneath a top glass panel and a bottom glass panel.

FIG. 33 is a perspective view from above and behind of a tonneau cover for a truck having an array of heated solar panels each having PV modules and elongate heater arrays.

### DETAILED DESCRIPTION OF THE PREFERRED EMBODIMENTS

This disclosure is submitted in furtherance of the constitutional purposes of the U.S. Patent Laws “to promote the progress of science and useful arts” (Article 1, Section 8).

As used herein, the term “sun shade” is used interchangeably with “sun screen” and is intended to cover any window or body panel device providing some degree of sun shading, concealment, or protection.

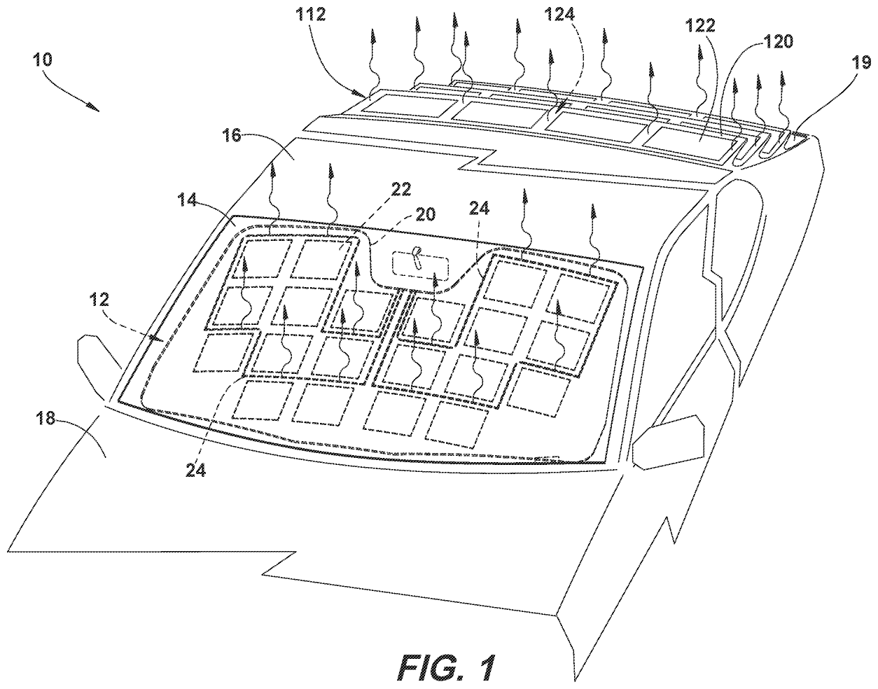

FIG. 1 is a perspective view from above of a vehicle, or automobile 10 having a stowable heated solar collector sun shade 12 provided beneath a front windshield, or window 14 of vehicle 10, as well as a rear sun shade, or louver 112 spaced over a rear windshield, or window 19. More particularly, sun shade, or sun screen 12 includes an array of electrically coupled together solar cell panels, or photovoltaic (PV) modules 22 carried on a stowable sun screen panel 20 that is opened and installed beneath windshield 14 in order to block or filter light transmission into an inside of vehicle 10. In summertime, sun screen 12 is used to reduce solar heating of an inside of a vehicle 10 and solar cell panels 22 convert and collect electric power for storage in one or more batteries on the vehicle. For the case of a primarily electrical vehicle, such power collection helps extend the vehicle performance and range by helping to recharge the operating batteries. Such power collection can also be used to charge a battery that is used to charge other devices, such as ebikes, electric scooters, phones, laptop computers, or electric tools associated with the vehicle. In wintertime, cold and wet weather can generate a risk for condensate occlusion on windshield, or window 14 and elongate heaters 24 drawing stored power from one or more batteries to mitigate or remove occlusion from above each solar panel 22 on windshield 14, such as frost, snow, or moisture buildup. Using such a system to charge a fat tire ebike can place the user in inclement weather in the mountains, including under snow and ice conditions. Likewise, sun shade 112 includes a plurality of solar cell photovoltaic (PV) modules 122 and elongate, circuitous heaters 124 on a rear louvered sun shade frame 120 over rear window 19.

Although sun shade 12 is shown beneath a vehicle windshield 14, it is understood that sun shade 12 could be placed atop a vehicle windshield 14 with solar cell panels 22 provided proximate a top surface to collect the sun and heaters 24 provided on a bottom surface to heat windshield 14 to remove frost or moisture buildup. Such sun shade can also be provided on/under a front windshield, a sun roof, a rear windshield, side windows, front, or on side and rear sun shades, or louvers or air deflectors, or any vehicle body panel. Likewise, such a panel can be affixed with suction cups or removable fasteners to an outer panel surface of a vehicle when parked and not in use, such as while parked in an airport parking lot. Furthermore, it is understood that any form of panel, including rolled up and folded panels, can be used with solar cell panels 22 and heaters 24 to provide heating that mitigates condensate occlusion from solar cell panels 22 on such panel. For example, such heated solar panel arrays can be provided on vehicle sun visors and pickup truck tonneau covers, and rear truck bed covers. Such heated solar cell panels 22 can be used on other areas, as previously mentioned, including on a vehicle roof 16 and a vehicle hood 18, or rendered as portable, stowable (folded or rolled) heated solar panels used by hikers, troops, or in mobile applications. Such heater solar cell panels 22 can also be affixed to exterior surfaces of a vehicle using adhesives. Optionally, the elongate heaters can be omitted to provide a sun screen capable of charging/recharging batteries associated with a vehicle. Such systems can also be used on combustion engine powered vehicles as well.

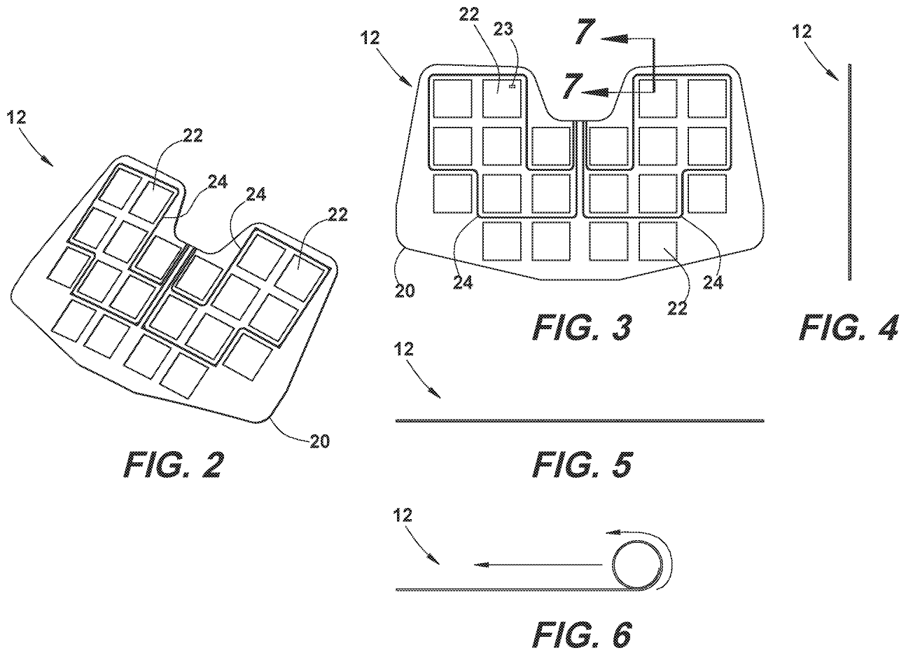

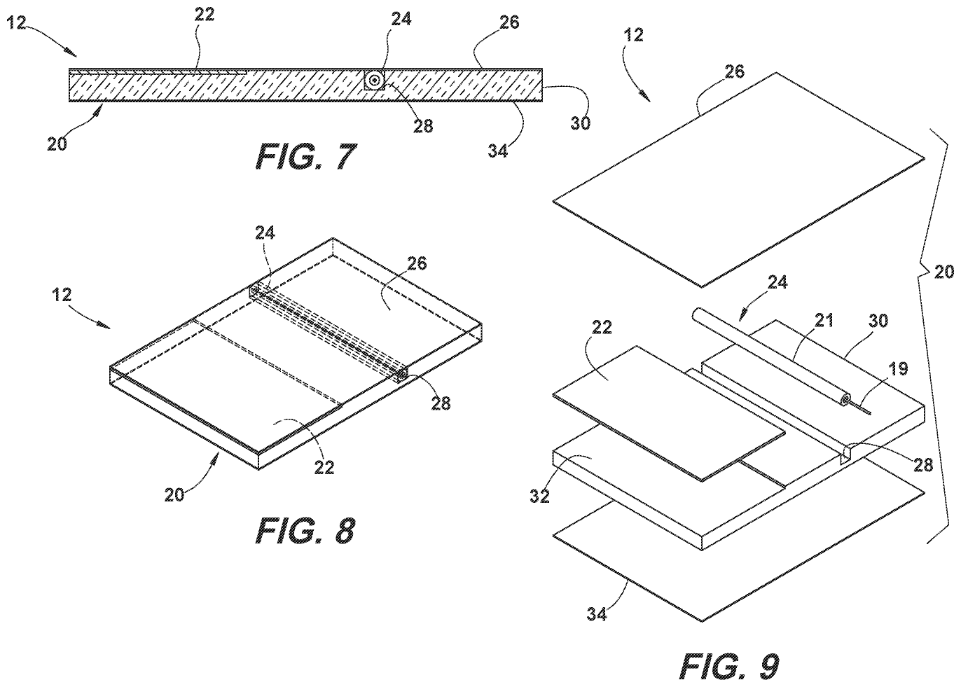

FIG. 2 is a perspective view from above of the heated solar panel sun shade 12 of FIG. 1. Left and right mirror image halves of panel 20 carry an array of solar panels, or cells 22 and a respective elongate, or rope heater 24 that circuitously encircles a group of solar cells 22 to impart local heating to a light transmissible windshield that is provided over sun shade 12 to mitigate condensate occlusion. In order to ease viewing, a clear top plastic sheet 26 (see FIG. 7) has been omitted from sun shade 12 in FIGS. 2-5, but is shown in FIGS. 7-9 in laminated assembly.

FIG. 3 is a plan view from above of a flat, unrolled configuration of the heated solar panel sun shade 12 of FIG. 2. Symmetric mirror image layout of an array of solar cell panels, or photovoltaic (PV) modules 22 onto panel 20 is shown with a pair of mirror image rope heaters 24 encompassing many of solar cell panels 22. Each PV module includes a square array of individual solar cells 23 electrically wired together to collect heat and generate electric current to one or more battery systems.

Elongate heater 24 of FIG. 3 can be formed from any of a number of elongate heaters, such as rope heaters having a linear elongate heater tube having a plastic outer tube, such as a PTFE high temperature tube with an inner Nichrome (or Nichromium) resistance heating wire powered with electric current. In one case, the rope heater is a heat generating resistance wire having an elongate encasement comprising a cover segment of plastic (such as PTFE) having an inner cavity of thermally transmissive, temperature mitigating, and electrically insulative material encompassing the elongate heating wire contained within the inner cavity. Optionally, a such a tube can have Indium Tin Oxide coating in an inner bore of the tube, or a Positive Temperature Coefficient (PTC) heating element within the bore. Such outer tube can also be filled with an epoxy or other filler material that increases thermal mass. Such tube can also take on any of a number of shapes, or cross-sections including round, elliptical, square, rectangular, tear drop, web-shaped, or any other suitable configuration for carrying and encasing the core heating element (Nichrome wire, Indium Tin Oxide inner coating, or PTC heater). It is also understood that such sun shade 12 can omit the top clear plastic layer.

FIGS. 4 and 5 show heated solar panel sun shade 12 in side and front edge views. FIG. 6 illustrates one technique for stowing sun shade 12; namely by rolling flexible sun shade 12 into a tube. Optionally, individual fold lines can be imparted into panel 20 to facilitate folding such sun shade 12 into an accordion folded rectangular pattern. Other stowage patterns can also be realized.

FIG. 7 is a simplified cross-sectional view of a selected rectangular segment of heated solar panel sun shade 12 taken along line 7-7 of FIG. 3. More particularly, panel 20 comprises a top light transmissible, or clear plastic sheet, or layer 26, a central foam core layer 30, and a bottom radiant heat reflective layer 34, such as Mylar, or aluminum foil. A circuitous groove 28 in layer 26 and core 30 is provided to receive elongate heater 24 according to one construction. Solar cell panel, or photovoltaic (PV) module 22 is adhesively affixed into a recess in core 30 beneath clear layer 24. Layers 24 and 34, core 30, heater 24 and solar cell module 22 are all vacuum bagged and adhesively bonded together according to one construction. Optionally, groove 28 can be eliminated and rope heater 24 can be constructed from a small diameter PTFE tube with an inner Nichrome resistance heating wire that is pressed into a top surface of foam core 30, or sits atop core 30 while clear plastic top sheet 26 is affixed thereatop.

FIG. 8 is a perspective view from above of the selected segment of the heated solar panel sun shade 12 of FIG. 7. More particularly, panel 20 shows elongate groove, or recess 28 in panel 20 for receiving clear layer, or plastic sheet 24 flush relative to a top surface. Solar cell panel 22 is also recessed into a top surface of panel 20.

FIG. 9 is an exploded perspective view from above of the selected segment of the heated solar panel sun shade 12 of FIG. 8. More particularly, panel 20 comprises a translucent, light transmitting top surface 26, such as a flexible plastic top sheet, a foam core 30, and a bottom heat reflective sheet 34. Elongate, or rope heater 24 is received in a circuitous path, or groove 28 formed in core 32 and solar panel 26 is received in a similar recess 32 in core 30. Rope heater 24 comprises a central resistance heating wire 21, such as a Nichrome resistance heating wire, and an outer temperature mitigating, thermally conductive and electrically insulative plastic covering 23, such as a polytetrafluoroethylene (PTFE) cover, or tube. According to one construction, rope heater is one of a number of PTFE (or high temperature plastic) covered or tubular heaters having a resistive heating wire contained therein, such as shown in U.S. Pub 20200340660 A1, herein incorporated by reference.

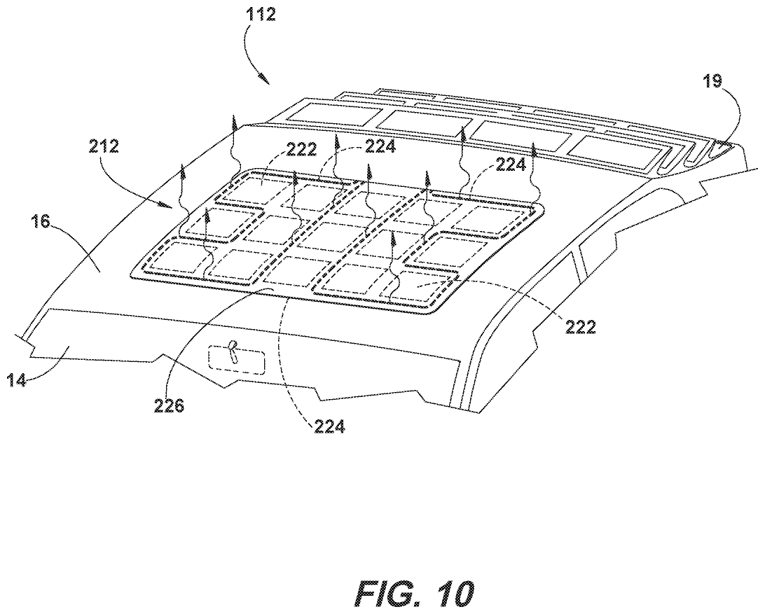

FIG. 10 is a perspective view from above of a vehicle roof 16 for a vehicle 10 having a heated solar panel array 212 integrated onto a top surface of roof 16. More particularly, heated solar panel array 212 includes an array of electrically coupled together solar cell panels, or photovoltaic (PV) modules 222 and circuitous elongate heaters 224 configured to distribute heat about the array of modules 222. As shown in FIG. 10, heated solar panel array 212 can be implemented in combination with one or more of arrays 12 and 112 shown in FIG. 1. Array 222 is forward of spoiler array 112 above rear window 19 and aft of front windshield 14.

As shown in FIG. 10, heated solar panel array 212 is formed as a vacuum-bagged and adhesively bonded together array 212 including a bottom plastic carrier layer 234, photovoltaic (PV) modules 222, elongate heaters 224 and clear, or light transmissible plastic top layer 226. The assembly of array 212 is then adhesively affixed atop roof 16. Optionally, fasteners and/or trim moldings can be used to affix array 212 atop roof 16. According to one construction layers 226 and 234 are each formed from a thin sheet of polycarbonate. Optionally, layer 234 can be formed from a composite material, such as a carbon fiber sheet or other suitable support sheet.

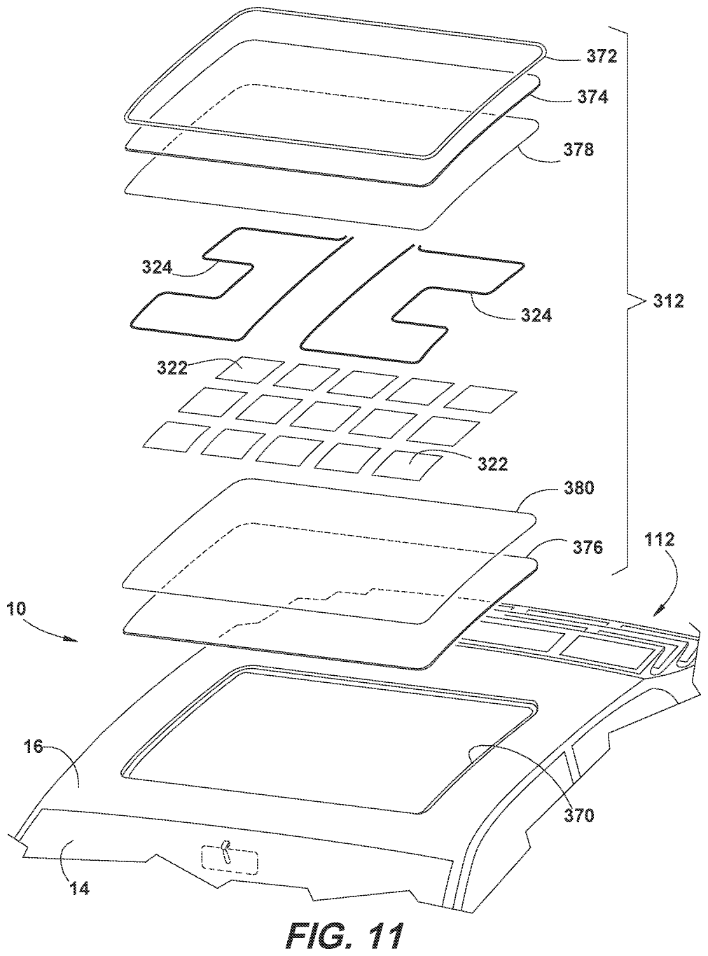

FIG. 11 is an exploded perspective view from above of a vehicle roof 16 on vehicle 10 having a heated solar panel array 312 including and integrated into a glass roof/skylight portion of roof 16 supported in roof opening 370 providing an optional construction over that shown in FIG. 10. In some cases, array 312 can encompass an entire roof top on a vehicle. More particularly, a pair of circuitous elongate heaters 324 are arranged about an array of photovoltaic (PV) modules 322 and sandwiched between a pair of sheets of vinyl interlayer, or polyvinyl butyral (PVB) film 378 and 380 and further sandwiched between two layers of glass 374 and 376. Such sandwich construction is similar to how vehicle front windshield safety glass is manufactured, but two layers of interlayer 278 and 280 are provided. Optionally, a single interlay of PVB film could be used on top or below the PV modules and heaters. The resulting construction uses opposed pressure rollers and heat to join together the sandwiched together layers. The sandwich assembly of glass 374 and 376, PVB interlayers 378 and 380, heaters 324, and PV modules 322 (and any associated sensors) are then sealed with urethane (not shown) into sunroof opening 370 of roof 16 and a circumferential trim piece 372 is affixed thereatop with fasteners and/or adhesive, or such fasteners (and a gasket seal) can be used to retain the resulting assembly onto associated roof structural members.

As shown in FIGS. 1, 10 and 11, one suitable PV module is a bare module, large scale PV module group available from Ascent Solar Technologies, Inc., (www.ascentsolar.com), 12300 Grant St., Thornton, CO 80241-3120 USA. Another suitable PV module is a PowerFilm Solar rollable solar panel available from PowerFilm, Inc. 1287 XE Place Ames, IA 50014 USA. Yet another suitable solar panel is available as an eFlex lightweight and flexible solar panel available from Flisom AG, Gewerbestrasse 16, 8155 Niederhasli, Switzerland.

Also as shown in FIGS. 1, 10 and 11, elongate heaters 24, 124 and 224 can be formed from any of a number of elongate heaters, such as rope heaters having a linear elongate heater tube having a plastic outer tube, such as a PTFE high temperature tube with an inner Nichrome (or Nichromium) resistance heating wire. In one case, the rope heater is a heat generating resistance wire having an elongate encasement comprising a cover segment of plastic (such as polytetrafluoroethylene (PTFE), such as a thin round cross-section PTFE tubing, having an inner cavity of thermally transmissive, temperature mitigating, and electrically insulative material encompassing the elongate heating wire contained within the inner cavity. Optionally, a such a tube can have Indium Tin Oxide coating in an inner bore of the tube, or a Positive Temperature Coefficient (PTC) heating element within the bore. Such outer tube can also be filled with an epoxy or other filler material that increases thermal mass. Such tube can also take on any of a number of shapes, or cross-sections including round, elliptical, square, rectangular, tear drop, web-shaped, or any other suitable configuration for carrying and encasing the core heating element (Nichrome wire, Indium Tin Oxide inner coating, or PTC heater). It is also understood that such sun shade 12 can omit the top clear plastic layer. Further optionally, strips, webs, circuitous paths, or tracks of Indium Tin Oxide or Positive Temperature Coefficient (PTC) heater material can be used to form elongate heaters about PV modules in an array.

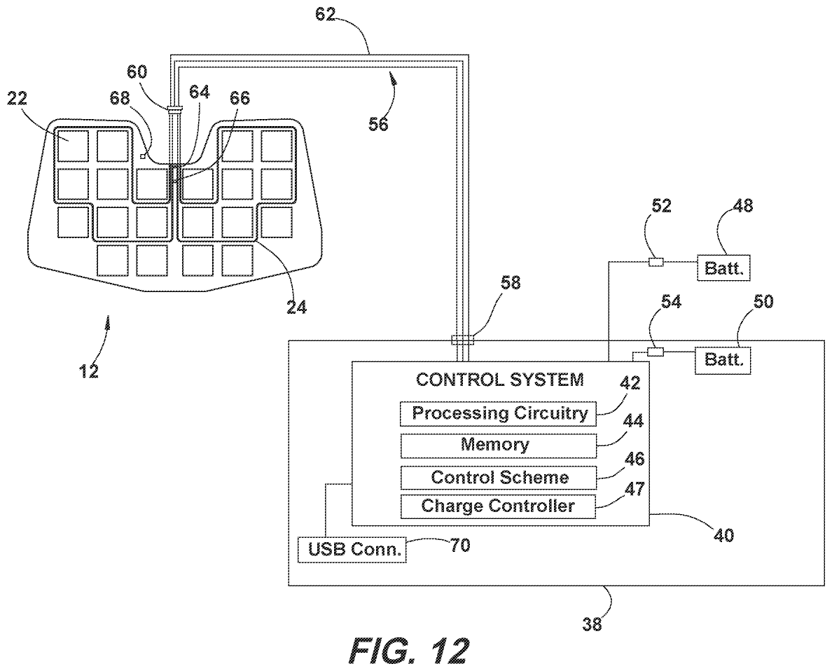

FIG. 12 is a simplified block diagram of the heated solar panel sun shade 12 of FIG. 1-9 with a control and power system module 38 used to supply and store power with the heated solar panel sun shade 12. More particularly, sun shade 12 includes an array of solar cell panels, or photovoltaic (PV) modules 22, a pair of elongate heaters 24, an occlusion, or light detector 64, and a pair of thermal sensors 66 and 68. A wiring harness 56 extends between sun shade 12 and module 38 with pairs of electrical connectors 58 and 60 at each end to facilitate maintenance, installation, and repair. Wiring harness 56 comprises an array of parallel individual insulation covered electrical conductors, or wires 62.

Module 38 of FIG. 12 includes a control system 40 including processing circuitry 42, memory 44, charge controller 47 and a control scheme 46 in the form of an algorithm that directs operation of heaters 24 based on feedback signals from sensors 64, 66 and 68. A USB connector and interface are also coupled with control system 40 to enable charging of one or more batteries 48 and 50. Battery 50 is inside of module 38 and comprises a portable lithium ion battery connected with an electrical power supply interface connector 54 with control system 40. Optionally, battery 50 can be a battery storage system in a truck of a vehicle configured for charging associated power tools, ebikes, scooters, electric motorcycles, electric UHVs or ATVs, electric snowmobiles, or other electric devices or tools. An external vehicle battery 48, either a starting battery or a storage battery for an electric vehicle, is also connected with an electrical power supply interface connector 52 with control system 40. A charging algorithm in control scheme 46 with charge controller 47 can direct when power is used to top off or trickle charge battery 48 and/or battery 50, as well as when to apply heat via heaters 24 depending on detected need from temperature conditions received as signals from one or more of sensors 64, 66 and 68.

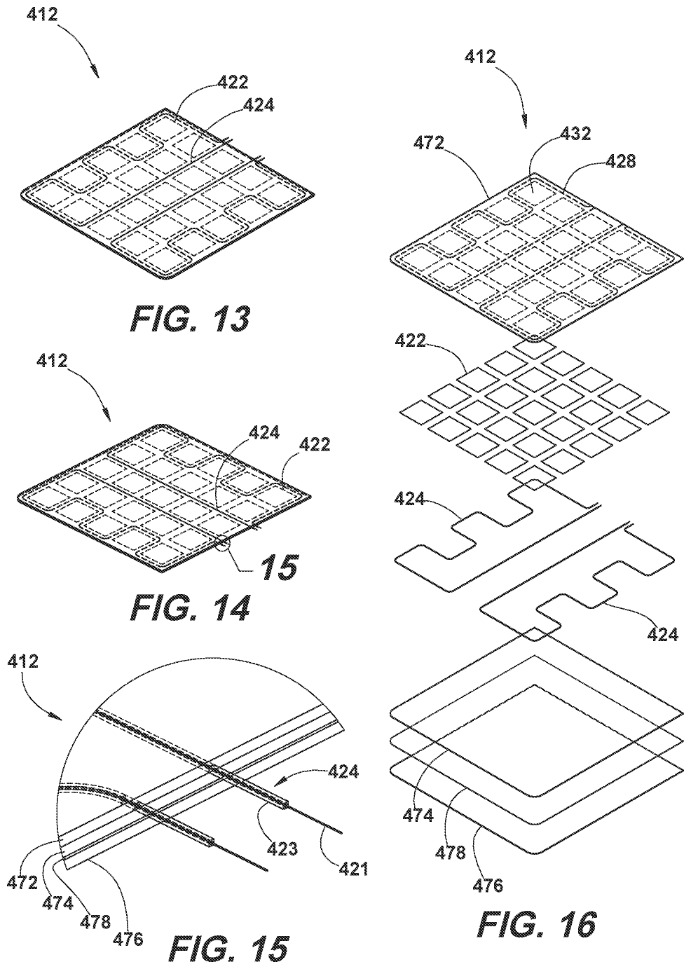

FIG. 13 is a perspective view from above and in front of an alternative vehicle roof having a heated solar panel assembly, or array 412 integrated into a laminated glass roof or sunroof of the vehicle having a polycarbonate top surface with an array of PV modules 422 encompassed by and proximate to a pair of elongate heaters 424 provided beneath the top surface. Array 412 can for a sunroof portion of a vehicle roof or can form an entire rooftop assembly for a vehicle. Optionally, such array 412 can be a steel roof panel having such an array with a light transmissible polycarbonate top surface and PV modules and heaters provided atop the roof panel and beneath the top surface.

FIG. 14 is a perspective view from above and behind of heated solar panel assembly, or array 412 of FIG. 13. PV modules 422 and elongate heaters 424 are shown in a rear side view from above.

FIG. 15 is an enlarged view of heated solar panel assembly, or array 412 taken from encircled region 15 of FIG. 14. More particularly, an outer polycarbonate sheet, or layer 472 is affixed atop a pair of laminated safety glass layers 474 and 476 that are affixed together with a middle, or interlayer of polyvinyl butyral (PVB) film 478. When heated and rolled together, layers 474, 478 and 476 form an automotive safety glass as understood in the field. Each elongate heater 424 is provided between layer 472 and a top surface of layer 474. According to one construction, each heater 424 is formed from an inner heat generating wire 421 and an outer peak temperature mitigating, thermally transmissive, and electrically insulating cover 423, such as polytetrafluoroethylene (PTFE) or some other suitable elevated temperature plastic. Wires 421 exit array 412 along an edge where they connect with a power supply wire (not shown) and a wiring harness. Layer 472 is affixed atop layer 474 with an adhesive, sealant, or bonding material that is optically transmissive, or clear. Other adhesives, fasteners, seals, and/or affixation mechanisms are also suitable. According to one construction, one liquid adhesive for bonded laminate assembly construction or otherwise attachment of an assembled and complete intermittently heated solar PV product unit onto an existing vehicle sunroof (or the like) is ResinLab UV7820 Clear. This is a one component UV curable acrylate that cures in visible light, and is available from ResinLab/Ellsworth Adhesives, N109 W13300 Ellsworth Drive, Germantown, WI 53022, United States.

FIG. 16 is an exploded perspective view of heated solar panel assembly, or array 412 of FIGS. 13-15. More particularly, assembly 412 includes a pair of elongate heaters 424 and an array of PV modules 422 adhesively affixed between a clear, top polycarbonate sheet 472 and a lower glass layer 474. Glass layers 474 and 476 each comprises a sheet of tempered glass joined together with heat and/or pressure with a sheet, or layer of polyvinyl butyral (PVB) film to together for a safety glass, such as a sunroof or rooftop glass laminate. According to one construction, polycarbonate sheet 472 has apertures 432 and grooves 428 sized and arranged to receive each PV module 422 and elongate heater 424 in sandwiched assembly to provide a uniform thickness in assembly. Optionally, a light transmissive adhesive or coating can be substituted to fill any gaps caused by differences in thickness of the resulting laminate assembly. Further optionally, one or more pieces of a polyvinyl butyral (PVB) film can be arranged to provide varying thicknesses that offset thicknesses in assembly from the PV modules 422 and elongate heaters 424.

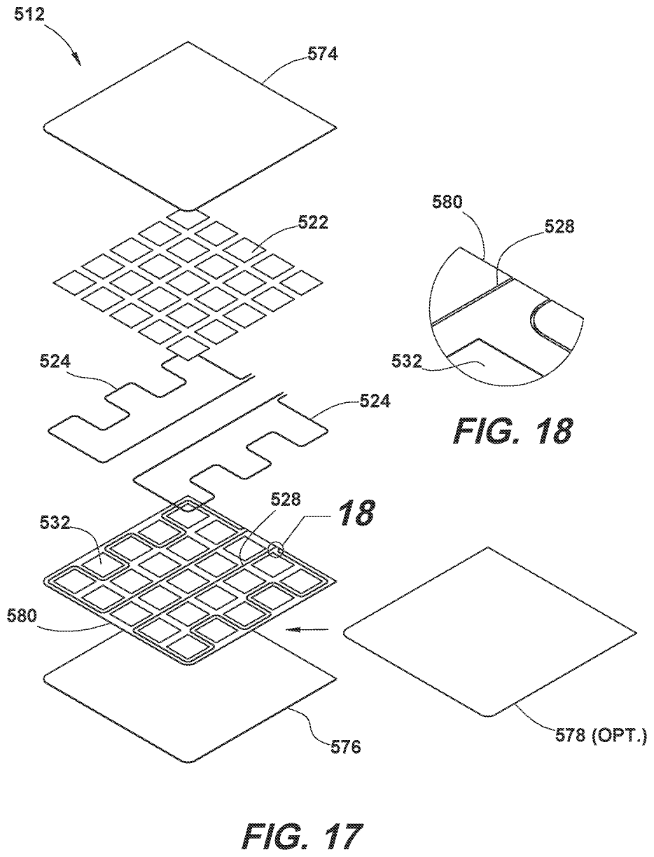

FIG. 17 is a perspective view from above and in front of a second alternative vehicle roof heated solar panel assembly 512 having a heated solar panel array of individual PV modules 522 and elongate heaters 524 integrated into a laminated glass roof or sunroof of a vehicle having a plastic, or polycarbonate intermediate layer 578 that can be added optionally. More particularly, an array of individual PV modules 522 and a pair of mirror-image elongate heaters 524 that traverse between modules 522 are laminated between top glass layer 574 and bottom glass layer, or sheet 576 with a variable depth plastic sheet 580 that accommodates thickness changes in the resulting laminate from PV modules 522 and heaters 524. In one case, plastic layer 580 is a polyvinyl butyral (PVB) film that has machined cavities to vary thickness, or is made from multiple layers, or is molded with such varying thicknesses. Optionally, plastic layer 580 is a layer of ethylene vinyl acetate (EVA) or a layer of polyurethane. Further optionally, plastic layer can be formed from polycarbonate or any other suitable plastic mid-layer that enables varying thicknesses between members of the resulting laminate provided by rectangular recesses 532 for receiving PV modules 522 and grooves 528 for receiving elongate heaters 524.

FIG. 18 is an enlarged view of the middle plastic layer 580 for the heated solar panel assembly taken from encircled region 18 of FIG. 17. More particularly, middle layer 580 includes rectangular recesses 532 sized to receive complementary individual PV modules (and connecting traces) and elongate grooves 528 sized to receive individual elongate heaters. In one case, recesses 532 and grooves 528 are molded in. In another case, they are machined in. In a third case, middle layer 580 is made from laminated layers that impart such thickness changes. Finally, a clear cured adhesive or resin layer can be used in substitution for layer 580.

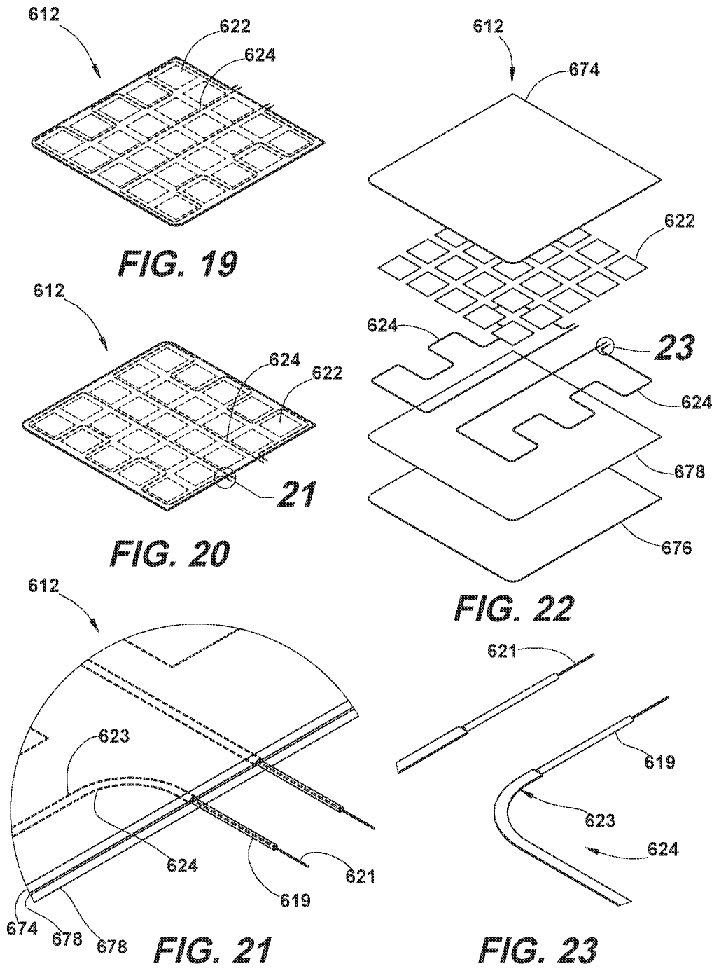

FIG. 19 is a perspective view from above and in front of another alternative vehicle roof having a heated solar panel assembly, or array 612 integrated into a laminated glass roof or sunroof of the vehicle having an array of PV modules 622 encompassed by and proximate to a pair of alternate construction elongate heaters 624 provided between a top layer and a bottom layer of tempered safety glass. Array 612 can for a sunroof portion of a vehicle roof or can form an entire rooftop assembly for a vehicle.

FIG. 20 is a perspective view from above and behind of the heated solar panel assembly 612 of FIG. 19. A rectangular array of electrically interconnected PV modules 622 a provided in assembly 612 with a pair of elongate heaters 624 extending between individual modules 622 to provide heat that removes condensate occlusion from assembly 612.

FIG. 21 is an enlarged view of the heated solar panel assembly 612 taken from encircled region 21 of FIG. 20. More particularly, elongate heater 624 is sandwiched between a top and a bottom pair of sheets 674 and 676 of tempered safety glass that are joined together with an intermediate layer of polyvinyl butyral (PVB) film 678 using a rolling process involving heat and/or pressure. Elongate heater 624 is formed from a heat generating ink trace 623 that exits assembly 612 as a conductive wire 621 and an insulative covering 619 where current flow through trace 623 generates heat output.

FIG. 22 is an exploded perspective view of the heated solar panel assembly 612 of FIGS. 19-21. More particularly, PV modules 622 and elongate heaters 624 are provided between top layer 674 and bottom layer 676 of tempered safety glass with an intermediate layer of polyvinyl butyral (PVB) film 678 provided beneath heaters 624. In one case, heaters 624 are printed onto film 678. Optionally, heaters 624 can be printed onto an inner surface of glass layers 674 and 676.

FIGS. 23 is an enlarged view of one of the elongate heaters taken from encircled region 23 of FIG. 22. PTC heater trace 623 of heater 624 terminates at each end with a conductive wire 621 encased in an insulated cover 619.

According to one construction, an electrically conductive, yet partially resistive, PTC ink for generating a trace is available as Loctite brand ECI 8000 E & C Series (including ECI 8120 PTC printable ink) from Henkel Corporation 14000 Jamboree Road, Irvine, CA 92606, United States. Optionally, a trace of indium tin oxide can be used. Further optionally, any other form of ink PTC traces can be used.

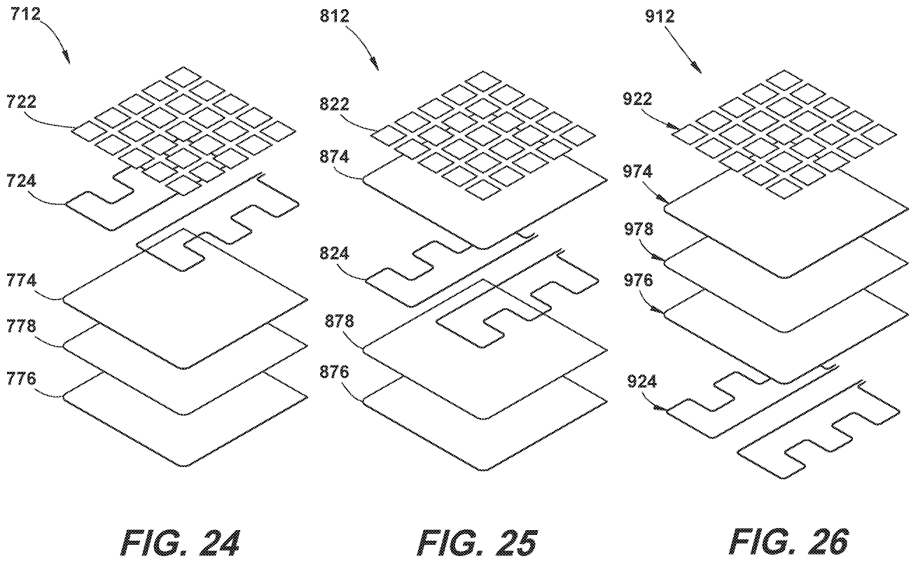

FIG. 24 is a simplified perspective view of a laminated glass body or roof heated solar panel assembly 712 having a first lamination configuration relative to a pair of laminated glass panels 774 and 776 with both an array of PV modules 722 and an array of elongate heaters 724 provided on top of a top glass panel 774 using an adhesive. An intermediate layer of polyvinyl butyral (PVB) film 778 is laminated between glass panels, or layers 774 and 776.

FIG. 25 is a simplified perspective view of a laminated glass body or roof heated solar panel assembly 812 having a second lamination configuration relative to a pair of laminated glass panels 874 and 876 with an array of interconnected PV modules 822 on top of a top glass panel 874 and with pair of elongate heaters 824 laminated as a middle layer along with an intermediate layer of polyvinyl butyral (PVB) film 878 between a top glass panel 874 and a bottom glass panel 876.

FIG. 26 is a simplified perspective view of a laminated glass body or roof heated solar panel assembly 912 having a third lamination configuration relative to a pair of laminated glass panels 974 and 976 with an array of PV modules on top of a top glass panel 974 and a pair of elongate heaters affixed with adhesive to a bottom surface of the bottom glass panel 976. An intermediate layer of polyvinyl butyral (PVB) film 978 is laminated between glass panels, or layers 974 and 976.

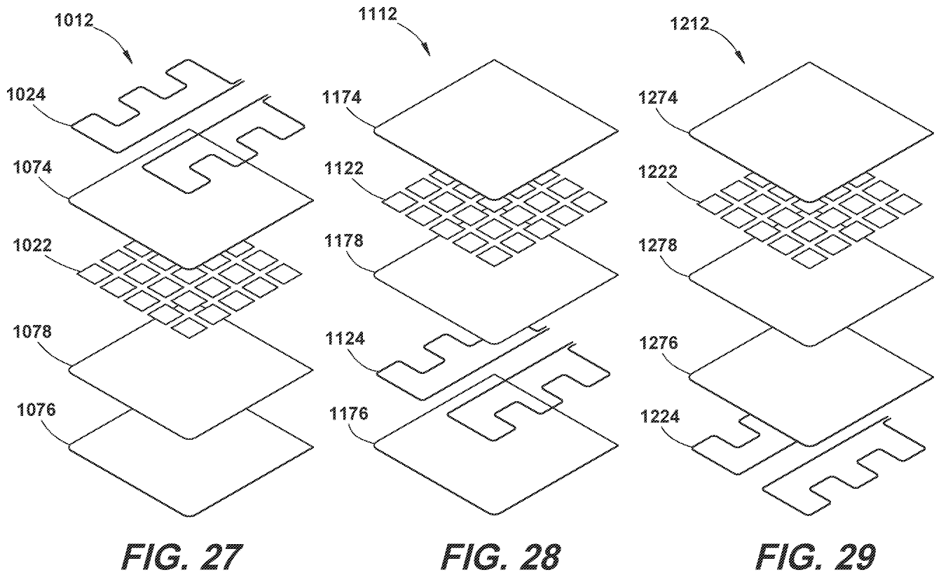

FIG. 27 is a simplified perspective view of a laminated glass body or roof heated solar panel assembly 1012 having a fourth lamination configuration relative to a pair of laminated glass panels 1074 and 1076 with an array of PV modules 1022 in a middle layer and a pair of elongate heaters adhesively affixed on top of top glass panel 1074. PV modules 1022 are laminated as a middle layer along with an intermediate layer of polyvinyl butyral (PVB) film 1078 between top glass panel 1074 and bottom glass panel 1076.

FIG. 28 is a simplified perspective view of a laminated glass body or roof heated solar panel assembly 1112 having a fifth lamination configuration relative to a pair of laminated glass panels 1174 and 1176 with both an array of PV modules 1122 and a pair of elongate heaters laminated with an intermediate layer of polyvinyl butyral (PVB) film 1178 in a middle layer between top glass panel 1174 and bottom glass panel 1176.

FIG. 29 is a simplified perspective view of a laminated glass body or roof heated solar panel assembly 1212 having a sixth lamination configuration relative to a pair of laminated glass panels 1274 and 1276 with an array of PV modules provided in a middle layer along with an intermediate layer of polyvinyl butyral (PVB) film 1278 in a middle layer between top glass panel 1274 and bottom glass panel 1276 beneath top glass panel 1274 and a pair of elongate heaters provided in a bottom layer beneath bottom glass panel 1276.

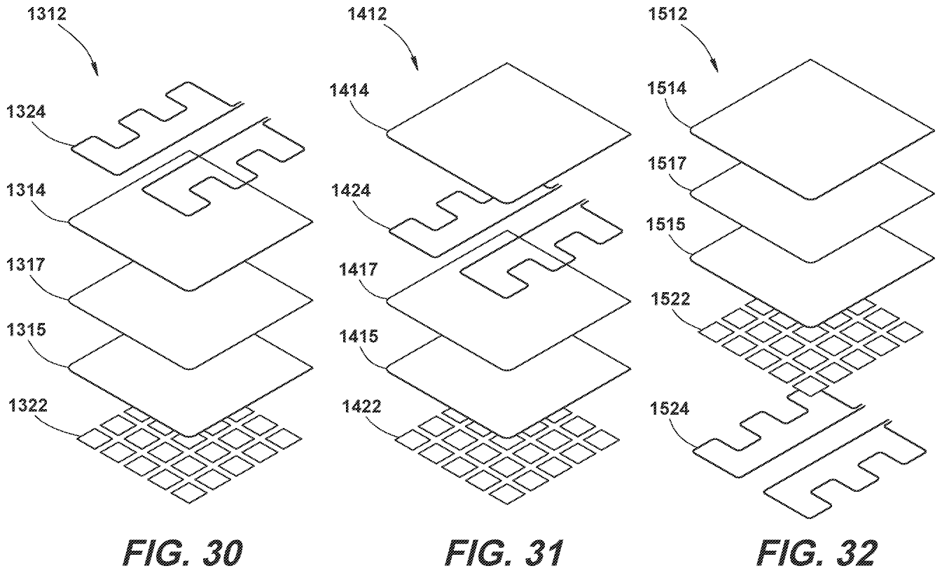

FIG. 30 is a simplified perspective view of a laminated glass body or roof heated solar panel assembly 1312 having a seventh lamination configuration relative to a pair of laminated glass panels 1374 and 1376 with an array of PV modules 1322 on a bottom layer and a pair of elongate heaters adhesively affixed atop a top glass panel 1374. An intermediate layer of polyvinyl butyral (PVB) film 1378 is laminated between glass panels, or layers 1374 and 1376.

FIG. 31 is a simplified perspective view of a laminated glass body or roof heated solar panel assembly 1412 having an eighth lamination configuration relative to a pair of laminated glass panels 1474 and 1476 with an array of PV modules 1422 in a bottom layer beneath a bottom glass panel and a heater array in a middle layer between a top glass panel 1474 and a bottom glass panel 1476. An intermediate layer of polyvinyl butyral (PVB) film 1478 is laminated between glass panels, or layers 1474 and 1476.

FIG. 32 is a simplified perspective view of a laminated glass body or roof heated solar panel assembly 1512 having a ninth lamination configuration relative to a pair of laminated glass panels 1574 and 1576 with both an array of PV modules 1520 and a pair of elongate heaters 1524 in a bottom layer beneath a top glass panel 1584 and a bottom glass panel 1586. An intermediate layer of polyvinyl butyral (PVB) film 1578 is laminated between glass panels, or layers 1574 and 1576.

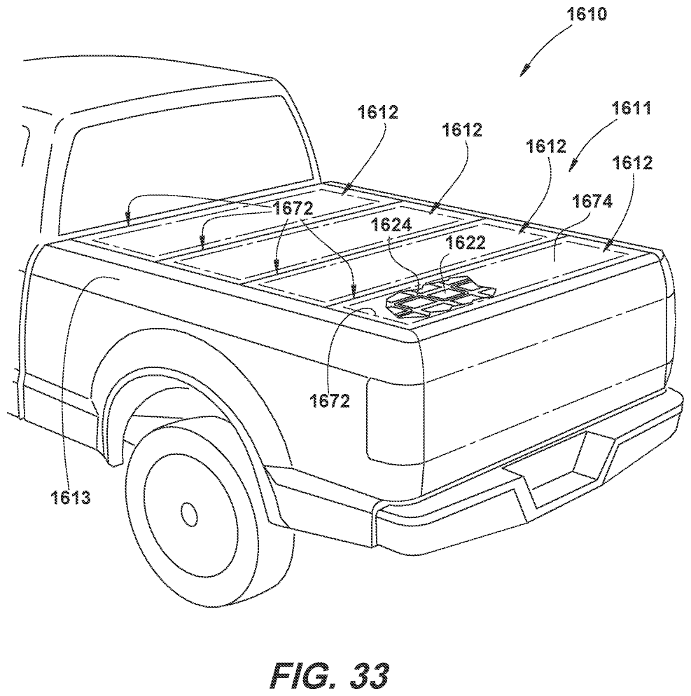

FIG. 33 is a perspective view from above and behind of a tonneau cover 1611 for a truck 1610 having a bed 1613 with an array of heated solar panels 1612 each having an array of individual PV modules 1622 and one or more elongate heaters 1624 embedded in each solar panel 1612 in a manner similar to those shown in FIGS. 1-32. According to one construction, heaters 1624 comprise one or more elongate heaters similar to heater 424 in FIG. 15 having a heat generating wire, such as a Nichrome wire, and an outer cover, such as a polytetrafluoroethylene (PTFE) cover. Optionally, any suitable elevated temperature plastic cover can be used. Further optionally, any suitable heat generating wire, or trace can be used. Further optionally, any construction for an elongate heater, including Positive Temperature Coefficient (PTC) or Indium Tin Oxide (ITO) traces can be used. Even further optionally, any construction disclosed for a heater in FIGS. 1-33 can be used on such tonneau cover 1611.

Elongate heater 1624 in each solar panel 1612 of FIG. 33 can take a circuitous or serpentine path similar to the path shown for heater 424 in FIG. 16 in order to distribute heat across solar panel 1612 to a top polycarbonate sheet 1674 provided atop PV modules 1622 and elongate heaters 1624. Optically transmissive sheet 1674 is affixed atop a rectangular aluminum structural frame 1672 for each solar panel 1612. Adjacent solar panels 1612 are joined together with elongate hinges 1672 that enable a user to fold up tonneau cover 1611 to gain access into bed 1613. A forwardmost solar panel 1672 can also be affixed to bed 1613 with a hinge 1672. Optionally, optically transmissive sheet 1674 can be a glass or plastic sheet, or any other suitable sheet that passes light energy into PV modules 1622 as taught herein variously with respect to constructions depicted in FIGS. 1-33. Optionally, elongate heaters 1624 can be powered via a remote battery or a vehicle battery in cases where sheet 1674 is occluded, such as after a snow storm or frost accumulation. An onboard vehicle computer and control system, or auxiliary controller can be used to initiate such power delivery from a storage battery to heaters 1624 when needed or when detected by an optical occlusion sensors provided atop or beneath one of sheet 1674. A method for clearing such occlusion can also be implemented with such control system.

A method is provided for heating a vehicle sun shade, comprising: providing a sun shade, at least one solar cell provided on the sun shade, and a heat source provided proximate the at least one solar cell. Delivering power to the heat source and generating heat to heat the at least one solar cell on the sun shade to mitigate any condensate or moisture occlusion of the at least one solar cell on the sun shade and/or a vehicle window in front and/or beneath the sun shade.

It is understood that each version of heated solar panel assembly shown in FIGS. 1-33 can benefit from use of electrically resistive heating elements in the form of relatively thin and flat circuit traces that are placed in proximity to solar PV modules or thin PV membranes. Such printed heating elements comprise one or more layers of a specialized electrically conductive and selectively resistive PTC (positive temperature coefficient) liquid ink applied to one or more surfaces of selected substrate materials within the complete heated solar panel assembly.

Using such liquid ink (or otherwise semi-liquid or hot-melt applied ink-like materials) that either dry, semi-harden or otherwise solidify, further provides for various methods of manufacture. Manufacturing methods may include, but not be limited to, circuit trace image printing or silk-screening methods for example.

Optionally, it is envisioned and anticipated that both 2-D flat and 3-D curved surface ink trace printing of the necessary electrically conductive and/or resistive heater circuit trace materials is to be applied (in optionally various widths and thicknesses) directly onto portions of selected glass and/or plastic substrates. Selected substrate shapes may include, but not be limited to flat, single-axis curved, and dual-axis curved (3-dimensional) curve-shaped automotive glass and plastic panel components.

Thin polycarbonate plastics and safety membrane materials may be utilized where dissimilar material bonding characteristics, life cycle temperature ranges, thermal expansion properties and the like are found to be within compatible limits for manufacturing, and a particular end use or application.

The combination and use of substantially thin membrane PV solar modules, printed PCT surface trace heater elements and electrically connective conductive circuit traces are conveniently flat in vertical dimension. When placed between laminated safety glass and other laminating materials these electrical components and physical features are relatively well protected from environmental elements and incidental mechanical or physical damage.

External insulated lead wires or ribbon wires connect the ink traces to the electrical circuitry encased within the laminated assembly at one or more edge locations (or optionally through one or more holes or ports within one or more of the laminate layers, not shown) of the completed assembled. The lead wires thus provide necessary external electrical connections both to and from the completed assembly.

Further, it is foreseeable and possible to “print” solar PV modules onto both rigid and flexible membrane substrates (including the conductive wire leads and traces). This strategy can then provide and incorporate for the printing of both during the manufacturing process allowing for an interlaced arrangement of heated areas adjacent to areas including the solar PV elements to melt and eliminate snow and ice.

Selective use of electrically insulative ink trace printing materials (Loctite brand) further allows for electrically insulated trace circuit cross-over points wherever necessary (or as desired). This construction is much like that used within existing printed circuit board technology, but on a significantly larger scale.

In compliance with the statute, embodiments of the invention have been described in language more or less specific as to structural and methodical features. It is to be understood, however, that the entire invention is not limited to the specific features and/or embodiments shown and/or described, since the disclosed embodiments comprise forms of putting the invention into effect. The invention is, therefore, claimed in any of its forms or modifications within the proper scope of the appended claims appropriately interpreted in accordance with the doctrine of equivalents.

I/we claim:

1. A vehicle sun shade, comprising:
a sun shade having a light receiving portion configured to be carried beneath a vehicle wind shield;
at least one solar cell provided in the light receiving portion; and
a heat source provided proximate the at least one solar cell traversing the light receiving portion configured to mitigate condensate occlusion of the at least one solar cell on a vehicle wind shield.

2. The vehicle sun shade of claim 1, wherein the sun shade is a front windshield sun shade.

3. The vehicle sun shade of claim 1, wherein the sun shade is a rear window sun shade.

4. The vehicle sun shade of claim 1, wherein the heat source comprises a resistance elongate heating wire having an elongate encasement comprising a cover segment of plastic having an inner cavity of thermally transmissive, temperature mitigating, and electrically insulative material encompassing the elongate heating wire contained within the inner cavity.

5. The vehicle sun shade of claim 4, wherein the cover segment of plastic comprises polytetrafluoroethylene (PTFE).

6. The vehicle sun shade of claim 1, wherein the heater comprises an elongate circuitous heater encompassing a portion of the at least one solar cell.

7. A vehicle sun shade, comprising:
a sun shade having a light receiving portion configured to be carried beneath a vehicle wind shield; and
at least one solar cell provided in the light receiving portion.

8. The vehicle sun shade of claim 7, further comprising a heat source provided proximate the at least one solar cell traversing the light receiving portion configured to mitigate condensate occlusion of the at least one solar cell on a vehicle wind shield.

9. A method is provided for heating a vehicle sun shade, comprising:
providing a sun shade, at least one solar cell provided on the sun shade, and a heat source provided proximate the at least one solar cell;
delivering power to the heat source; and
generating heat from the heat source responsive to delivering power to the heat source to heat the at least one solar cell on the sun shade to mitigate any condensate or moisture occlusion of the at least one solar cell on the sun shade and/or a vehicle window in front and/or beneath the sun shade.
